(19) United States
(12) Patent Application Publication
(10) Pub. No.: US 2012/0325758 A1
(43) Pub. Date: Dec. 27, 2012

(54) FIXING DEVICE FOR EXPANSION CARDS

(75) Inventors: XIAO-FENG MA, Shenzhen City (CN); LEI LIU, Shenzhen City (CN)

(73) Assignees: HON HAI PRECISION INDUSTRY CO. LTD., Tu-Cheng (TW); HONG FU JIN PRECISION INDUSTRY(ShenZhen) CO., LTD., Shenzhen City (CN)

(21) Appl. No.: 13/187,481

(22) Filed: Jul. 20, 2011

(30) Foreign Application Priority Data
Jun. 23, 2011 (CN) 201110170606.6

(51) Int. Cl. H05K 7/00

(52) U.S. Cl. 211/26

(57) ABSTRACT

A device for fixing a number of expansion cards includes a rack and a fixing member. The rack includes a top wall. The fixing member includes a plate detachably mounted to a bottom of the top wall, and a frame substantially perpendicularly extending down from the plate. The frame longitudinally forms a number of fixing portions to engage with corresponding ends of the expansion cards.

### BACKGROUND

1. Technical Field

The present disclosure relates to a device for fixing a plurality of expansion cards.

2. Description of Related Art

First ends of expansion cards are generally fixed to a chassis, while second ends of the expansion cards are cantilevered. As a result, when the expansion cards are long and are horizontally fixed to the chassis, the second ends of some of the expansion cards may droop to contact other expansion cards below, and a short circuit may occur.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an assembled, isometric view of an exemplary embodiment of a fixing device for expansion cards; the fixing device includes a fixing member.

FIG. 2 is an exploded, isometric view of FIG. 1, but viewed from another perspective.

FIG. 3 is an enlarged view of the fixing member of FIG. 2, but viewed from another perspective.

FIG. 4 is a partially assembled, isometric view of FIG. 2.

FIG. 5 is an assembled, isometric view of FIG. 4.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

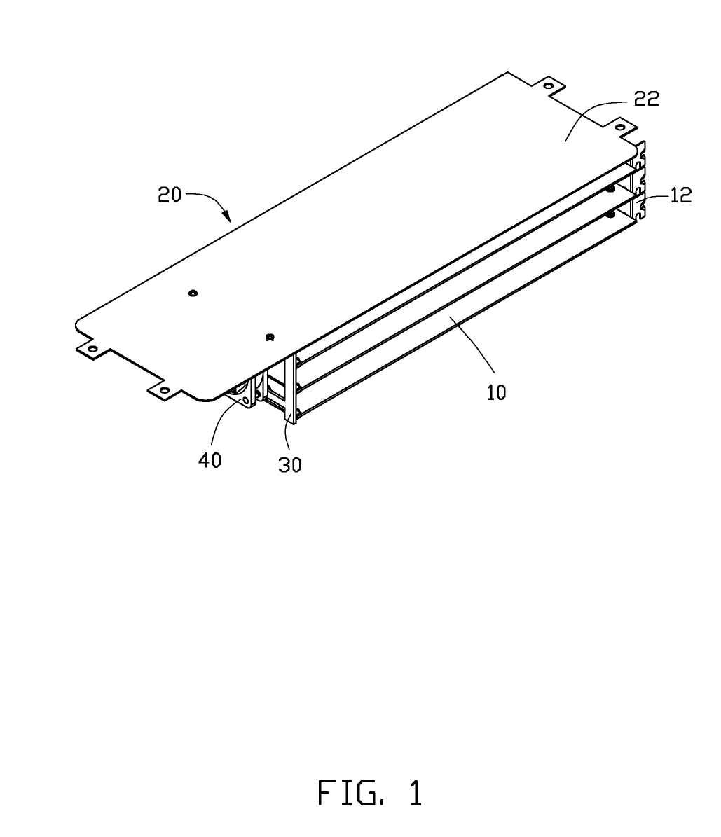

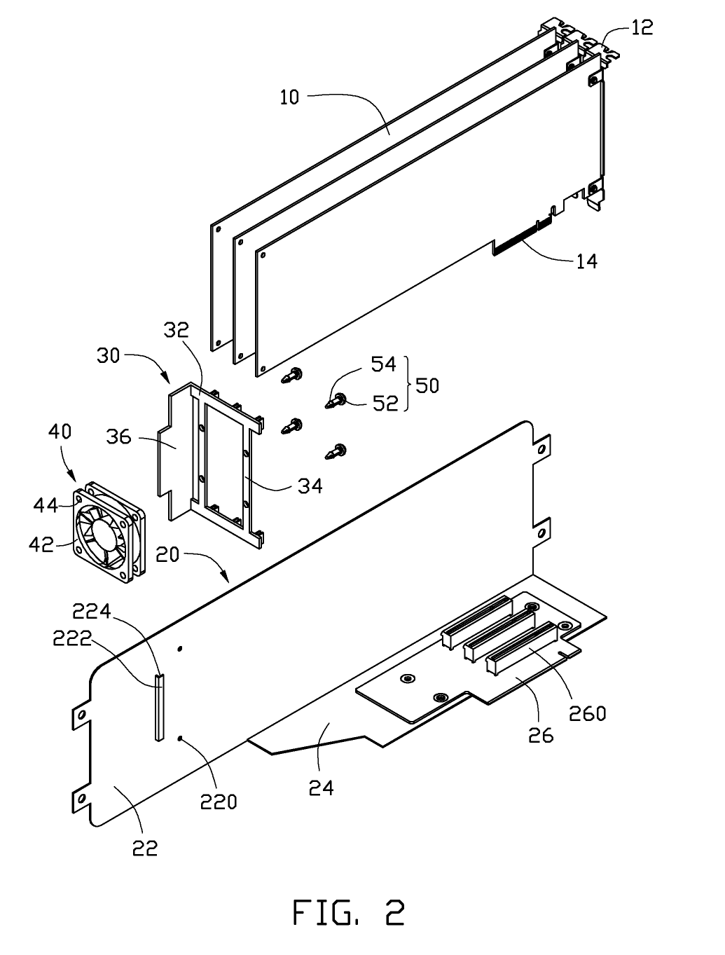

Referring to FIG. 1 and FIG. 2, an exemplary embodiment of a fixing device for fixing a plurality of expansion cards 10 includes a rack 20, a fixing member 30, a fan 40, and a plurality of fasteners 50.

A connection portion 14 extends from a bottom side of each expansion card 10. A substantially L-shaped cover plate 12 is mounted to a first end of each expansion card 10.

The rack 20 includes a top wall 22, a rear wall 24 substantially perpendicularly extending down from a rear side of the top wall 22, and a circuit board 26 mounted to an inner surface of the rear wall 24. A plurality of connectors 260 is mounted to an inner surface of the circuit board 26. The top wall 22 defines two through holes 220 in a first end of the top wall 22. A substantially L-shaped blocking portion 222 extends from to a bottom surface of the top wall 22, and bounds a receiving space 224 with the top wall 22. The receiving space 224 opposes the through holes 220 and a second end of the top wall 22 opposite to the first end.

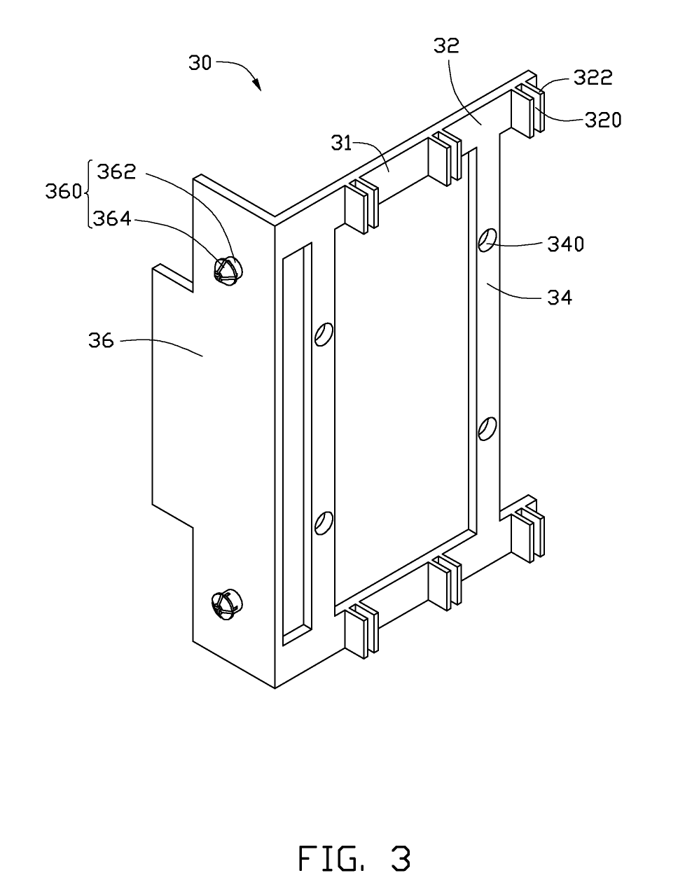

Referring to FIG. 3, the fixing member 30 is substantially L-shaped, and includes a frame 31 and a plate 36 substantially perpendicularly extending from a side of the frame 30. The frame 31 includes two arms 32 perpendicularly connected to opposite ends of a first side of the plate 36, and two ribs 34 substantially perpendicularly connected between the arms 32. Each arm 32 forms a plurality of fixing portions 320 on a side opposite to the plate 36. Each fixing portion 320 includes two parallel tabs 322 substantially perpendicularly extending from the arm 32. Two fixing holes 340 are defined in each rib 34. Two projections 360 protrude from a surface of the plate 36 opposite to the frame 30. Each projection 360 includes a pin 362 extending from the plate 36 and a tapered head 364 formed on a distal end of the pin 362.

Referring to FIG. 2, the fan 40 includes two spaced boards 42. Each board 42 defines four engaging holes 44 in four corners.

Each fastener 50 includes a blocking portion 52, and an extension portion 54 extending from a side of the blocking portion 52 with a tapered distal end. The diameter of the great end of the tapered distal end is greater than the diameter of the extension portion 54.

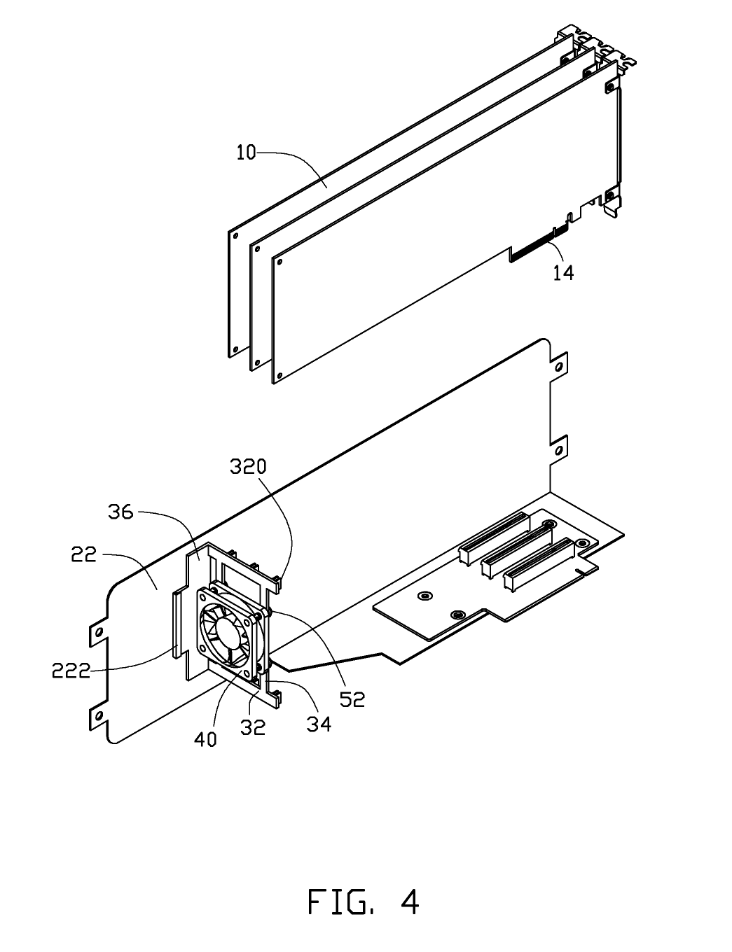

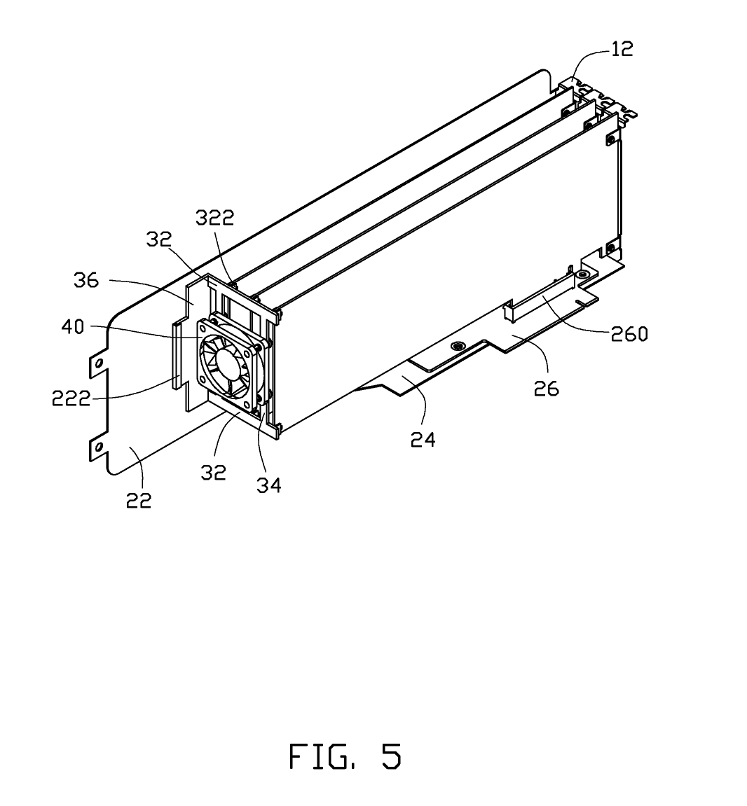

Referring to FIGS. 1, 4 and 5, in assembly, the extension portions 54 extend through the fixing holes 340 and engage in the engaging holes 44 of one of the boards 42, to fix the fan 40 to the first side surface of the frame 31 opposing the plate 36. The blocking portions 52 are blocked by the second side surface of the frame 30 opposite to the plate 36, distal ends of the extension portions 54 are blocked by an inner surface of the corresponding board 42. A second side of the plate 36 opposite to the frame 31 is inserted into the receiving space 224, and the projections 360 extend through the through holes 220, to fix the fixing member 30 to the bottom surface of the top wall 22. The heads 364 are blocked by a top surface of the top wall 22. The connection portions 14 are inserted into the corresponding connectors 260. A second end of each expansion card 10 opposite to the cover plate 12 is inserted into a corresponding fixing portion 320, and sandwiched between the corresponding tabs 322. The cover plates 12 are then fixed to a sidewall of a chassis (not shown).

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiments.

What is claimed is:

1. A fixing device for fixing an expansion card, the fixing device comprising:
a rack comprising a top wall; and
a fixing member comprising a plate mounted to a bottom of the top wall, and a frame extending down from the plate, wherein the frame forms a fixing portion to engage with an end of the expansion card.

2. The fixing device of claim 1, wherein the top wall defines two through holes, two projections protrude from the plate to engage in the through holes.

3. The fixing device of claim 2, wherein each projection comprises a pin extending through a corresponding one of the through holes, and a tapered head formed on a distal end of the pin and blocked by a top of the top wall.

4. The fixing device of claim 1, wherein the frame comprises two arms substantially perpendicularly extending from a side of the plate, the fixing portion extend from one of the arms.

5. The fixing device of claim 4, further comprising a plurality of fasteners and a fan, wherein the fan comprises two opposite boards, the frame further comprises two ribs substantially perpendicularly connected between the arms, two fixing holes are defined in each rib, the fasteners extend through the fixing holes and engage in one of the boards, to fix the fan to the fixing member.

6. The fixing device of claim 5, wherein each fastener comprises a blocking portion and an extension portion extending from the blocking portion, the extension portion has a tapered distal end.

7. The fixing device of claim 1, wherein the fixing portion comprises two tabs to sandwich the end of the expansion card.

8. The fixing device of claim 1, wherein a substantially L-shaped blocking portion is formed on the bottom of the top wall, a receiving space is bounded by the blocking portion and the bottom of the top wall to receive the plate.
